(19) United States
(12) Patent Application Publication
(10) Pub. No.: US 2025/0372351 A1
(43) Pub. Date: Dec. 4, 2025

(54) REFRACTORY COMPONENTS FOR A SEMICONDUCTOR PROCESSING CHAMBER

(71) Applicant: Lam Research Corporation, Fremont, CA (US)

(72) Inventors: David Joseph WETZEL, Santa Clara, CA (US); Eric A. PAPE, Santa Cruz, CA (US); Lin XU, Fremont, CA (US); John DAUGHERTY, Fremont, CA (US)

(21) Appl. No.: 19/120,431

(22) PCT Filed: Oct. 9, 2023
(86) PCT No.: PCT/US2023/076385

§ 371 Date: Apr. 11, 2025

Related U.S. Application Data
(60) Provisional application No. 63/420,863, filed on Oct. 31, 2022.

(51) Int. Cl. H01J 37/32; C23C 16/30; C23C 16/40; C23C 28/00

(52) U.S. Cl. CPC H01J 37/32477; C23C 16/30; C23C 16/40; C23C 16/405; C23C 28/32; C23C 28/34; C23C 28/345

(57) ABSTRACT

A component for use in a semiconductor processing chamber is provided. A component body has a process facing surface, wherein the component body comprises at least one of iron, iron alloy, nickel, nickel alloy, titanium, and titanium alloy. A coating is over the process facing surface, wherein the coating comprises at least one of a metal oxide, a metal fluoride, and a metal oxyfluoride, wherein the coating is at least 99% by weight pure and has a porosity of less than 0.1%.

### CROSS-REFERENCE TO RELATED APPLICATION

This application claims the benefit of priority of U.S. Application No. 63/420,863, filed Oct. 31, 2022, which is incorporated herein by reference for all purposes.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

In forming semiconductor devices semiconductor processing chambers are used to process the substrates. Some semiconductor processing chambers have component parts that are eroded during semiconductor processing. Coatings may be used to protect the component parts.

### SUMMARY

To achieve the foregoing and in accordance with the purpose of the present disclosure, a component for use in a semiconductor processing chamber is provided. A component body has a process facing surface, wherein the component body comprises at least one of iron, iron alloy, nickel, nickel alloy, titanium, and titanium alloy. A coating is over the process facing surface, wherein the coating comprises at least one of a metal oxide, a metal fluoride, and a metal oxyfluoride, wherein the coating is at least 99% pure by weight and has a porosity of less than 0.1%.

In another manifestation, a method for making a component for use in a semiconductor processing chamber is provided. A component body comprises at least one of iron, iron alloy, nickel, nickel alloy, titanium, and titanium alloy and has a process facing surface. An atomic layer deposition coating is provided over the process facing surface of the component body, wherein the atomic layer deposition coating comprises at least one of a metal oxide, a metal fluoride, and a metal oxyfluoride.

These and other features of the present disclosure will be described in more detail below in the detailed description and in conjunction with the following figures.

### BRIEF DESCRIPTION OF THE DRAWINGS

The present disclosure is illustrated by way of example, and not by way of limitation, in the figures of the accompanying drawings and in which like reference numerals refer to similar elements and in which:

FIG. 1 is a high level flow chart of an embodiment.

FIG. 2A-C is a schematic cross-sectional view of part of an embodiment

FIG. 3 is a schematic cross-sectional view of another component provided by an embodiment.

FIG. 4 is a schematic of a plasma processing chamber that may be used in an embodiment.

In the drawings, like reference numerals are sometimes used to designate like structural elements. It should also be appreciated that the depictions in the figures are diagrammatic and not to scale.

### DETAILED DESCRIPTION OF THE PREFERRED EMBODIMENTS

The present disclosure will now be described in detail with reference to a few preferred embodiments thereof as illustrated in the accompanying drawings. In the following description, numerous specific details are set forth in order to provide a thorough understanding of the present disclosure. It will be apparent, however, to one skilled in the art, that the present disclosure may be practiced without some or all of these specific details. In other instances, well-known process steps and/or structures have not been described in detail in order to not unnecessarily obscure the present disclosure.

Currently, semiconductor processing chambers for forming semiconductor devices have aluminum components. Such components can be aluminum to provide electrical and thermal characteristics that are useful in maintaining a plasma. Aluminum may also allow a reduction in weight and cost. Since aluminum can be eroded or damaged by some of the semiconductor processes, atmospheric plasma spray (APS) coatings on the order of 1-50 microns thick may be used to protect the aluminum component. APS morphologies and microstructures can cause particles and metal contamination that are not acceptable for the leading edge technology nodes.

Atomic layer deposition (ALD) coating may be used to coat an aluminum component in order to avoid defects and contaminants caused by APS coatings. Many ALD coatings result in heating the aluminum component to a temperature of around 200° C. Many aluminum substrate materials cannot withstand temperatures above 120° C. without reducing the mechanical strength. The maintenance of the mechanical strength of the aluminum component is needed in order for the aluminum component to safely maintain a low pressure environment for a semiconductor processing chamber.

Components made of refractory metals are able to maintain mechanical strength after being subjected to ALD temperatures. Some refractory metals are denser than aluminum and are less damage or etch resistant than aluminum in semiconductor processing environments. In addition, some components entirely made of refractory metal do not provide the uniform electrical current conduction and the uniform thermal conduction provided by aluminum.

In some embodiments, a component for a semiconductor processing chamber is provided comprising a refractory metal component body with a coating on a process facing surface with an ALD coating. In some embodiments, the component comprises a refractory metal component body with a coating and other features for providing a uniform electrical conductivity and appropriate thermal conductivity for spatially tailored temperature control of the aforementioned component.

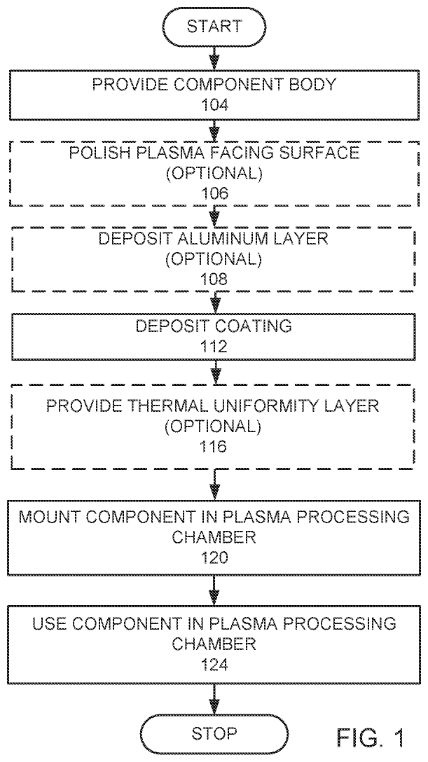

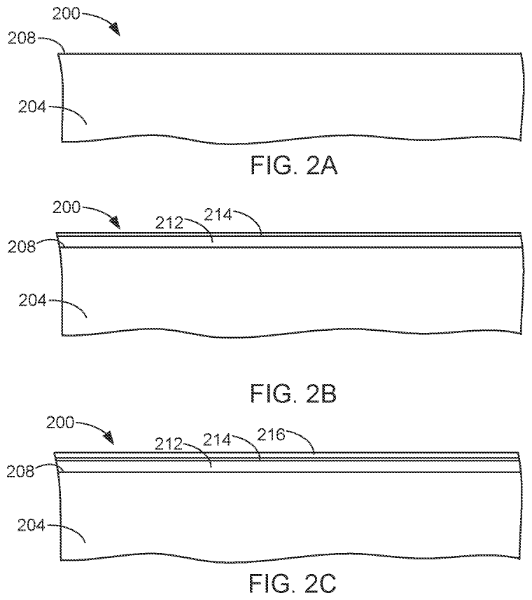

To facilitate understanding, FIG. 1 is a high level flow chart of a process used in an embodiment. A component body is provided (step 104). The component body is made of a refractory metal. In some embodiments, the refractory metal comprises one or more of iron, iron alloy, nickel, nickel alloy, titanium, and titanium alloy. For example, the component body may comprise at least one of stainless steel (SS), nickel super alloy; hereinafter referred to as NSAs, and titanium (Ti) and titanium alloy. In some embodiments, the NSA comprises nickel and one or more of molybdenum (Mo), cobalt (Co), and chromium (Cr). In some embodiments, the titanium alloy is Ti-6A1-4V, which has a unified number system designation of R56400. In some embodiments, the stainless steel is at least one of SAE 316L grade stainless steel, also known as A4 stainless steel or marine grade stainless steel, and AL-6XN stainless steel, with a unified numbering system designation N08367. FIG. 2A is a schematic cross-sectional view of part of a component body 204. The component body 204 has a process facing surface 208, also called the vacuum side of the component body 204.

In some embodiments, the process facing surface 208 is optionally polished (step 106). In some embodiments, the process facing surface 208 is polished to provide a roughness of less than 1 μm Ra. Ra roughness is an arithmetic average roughness described in ASME B46.1.

In some embodiments, an aluminum layer is optionally deposited on the process facing surface (step 108). In some embodiments, electroplating is used to provide an aluminum layer that is at least 99% pure by weight. In some embodiments, electroplating provides an aluminum layer that is at least 99.9% pure by weight. The process of electroplating involves a standard electrochemical cell where the part to be plated is the cathode and the anodes are ultra-high purity aluminum and both components are immersed in an electrolyte. In some embodiments, to provide an aluminum layer with sufficiently high purity, a conductive organic-based solution instead of a water-based solution is desired. In some embodiments, a bond layer may be provided between the component body and the aluminum layer. For example, for a stainless steel component body, a nickel phosphorous plating may be deposited as a bond layer to increase adhesion between the stainless steel component body and the aluminum layer. In some embodiments, the aluminum layer is deposited by cold spray. In some embodiments, electroplating provides a smoother surface than cold spraying. FIG. 2B is a schematic cross-sectional view of the component body 204 after the aluminum layer 212 has been deposited on the process facing surface 208 (step 108). In some embodiments, a passivated aluminum oxide layer 214 is formed over the aluminum layer 212. In some embodiments the aluminum oxide layer 214 is formed by at least one of anodizing aluminum and plasma electrolytic oxidation. In some embodiments, the aluminum layer 212 has a thickness in the range of 10 to 1000 μm. In some embodiments, the aluminum layer 212 has a thickness in the range of 30 to 500 μm. In some embodiments, the aluminum oxide layer 214 formed over the aluminum layer 212 has a thickness in the range of 15-100 μm.

A coating is deposited on the process facing surface 208 of the component body 204 (step 112). If the aluminum layer 212 is deposited, the coating is deposited on the aluminum layer 212 or aluminum oxide layer 214. If the aluminum layer 212 is not deposited, the coating will be in direct contact with the process facing surface 208. In some embodiments, the coating is one or more of a metal oxide, metal fluoride, and metal oxyfluoride. In some embodiments, the coating is deposited by at least one of atomic layer deposition (ALD), chemical vapor deposition (CVD), atmospheric plasma spraying (APS), and physical vapor deposition (PVD). In some embodiments, PVD may be chemically enhanced plasma vapor deposition or plasma enhanced physical vapor deposition. Atomic layer deposition and chemical vapor deposition provide conformal coatings that are helpful in coating irregularly shaped surfaces. In some embodiments, the deposition process of the coating causes the component body 204 to be heated to a temperature above 200° C. for a period of at least 600 minutes. For example, the coating may be yttria (Y₂O₃) deposited by ALD at a temperature of at least 200° C.

FIG. 2C is a schematic cross-sectional view of part of the component body 204 after a coating 216 has been deposited over the aluminum layer 212 and process facing surface (step 112). The coating 216 is thinner and more etch resistant than the aluminum layer 212. In some embodiments, the coating 216 has a thickness of less than 1 micron. In some embodiments, the coating 216 has a thickness in the range of 50 nm to 6000 nm. In some embodiments, the coating 216 has a thickness in the range of 50 nm to 3000 nm. In some embodiments, the coating 216 has a thickness in the range of 50 nm to 1000 nm. In some embodiments, the coating 216 has a thickness in the range of 50 nm to 500 nm.

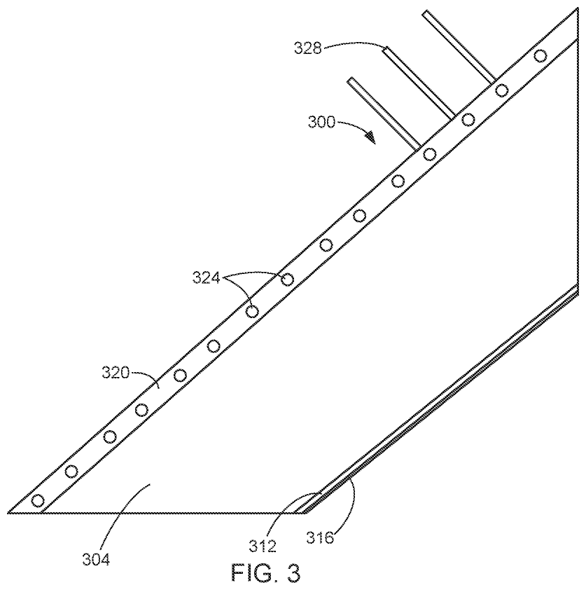

A thermal uniformity layer is optionally provided on the component body (step 116). FIG. 3 is a cross-sectional view of a component 300 provided in some embodiments. In some embodiments, the component 300 is a chamber liner comprising a component body 304, aluminum layer 312, and coating 316. A thermal uniformity layer 320 is placed on a surface of the component body 304 on the atmosphere side of the component body 304 that is the opposite side of the component body 304 from the coating 316 and aluminum layer 312 and the process facing surface. In some embodiments, the thermal uniformity layer 320 has thermal channels 324. The thermal channels 324 carry a thermal fluid that may be used to heat or cool the thermal uniformity layer 320. In some embodiments, the thermal uniformity layer 320 comprises aluminum. Aluminum has a high thermal conductivity allowing for a more uniform thermal distribution. In some embodiments, the thermal uniformity layer 320 comprises thermal fins 328 or other thermal control features. In some embodiments, the thermal uniformity layer 320 has a thickness in the range of 1 to 20 mm. In some embodiments, the thermal uniformity layer 320 may cover only part of the atmosphere side of the component body 304 so that part of the atmosphere side of the component body 304 is not covered by the thermal uniformity layer 320.

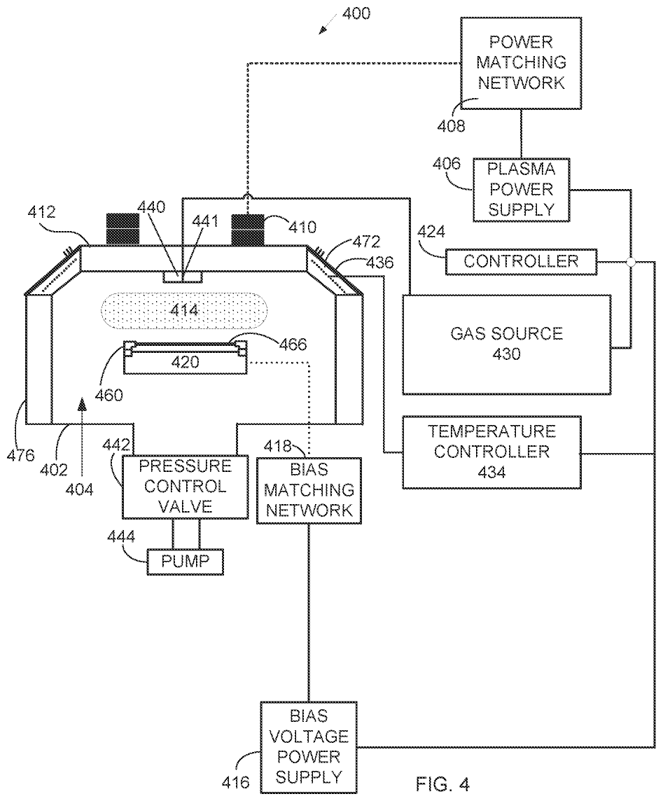

The component body 204 is mounted in a semiconductor processing chamber (step 120). To facilitate understanding, FIG. 4 schematically illustrates an example of a semiconductor processing chamber system 400 that may be used in an embodiment. The semiconductor processing chamber system 400 includes a plasma reactor 402 having a semiconductor processing chamber 404 therein. A plasma power supply 406, tuned by a power matching network 408, supplies power to a transformer coupled plasma (TCP) coil 410 located near a dielectric inductive power window 412 to create a plasma 414 in the semiconductor processing chamber 404 by providing an inductively coupled power. A chamber liner, such as a pinnacle 472, extends from a chamber wall 476 of the semiconductor processing chamber 404 to the dielectric inductive power window 412 forming a pinnacle ring. The pinnacle 472 is angled with respect to the chamber wall 476 and the dielectric inductive power window 412. For example, the interior angle between the pinnacle 472 and the chamber wall 476 and the interior angle between the pinnacle 472 and the dielectric inductive power window 412 may each be greater than 90° and less than 180°. The pinnacle 472 provides an angled ring near the top of the semiconductor processing chamber 404, as shown. The TCP coil (upper power source) 410 may be configured to produce a uniform diffusion profile within the semiconductor processing chamber 404. For example, the TCP coil 410 may be configured to generate a toroidal power distribution in the plasma 414. The dielectric inductive power window 412 is provided to separate the TCP coil 410 from the semiconductor processing chamber 404 while allowing energy to pass from the TCP coil 410 to the semiconductor processing chamber 404. A wafer bias voltage power supply 416 tuned by a bias matching network 418 provides power to an electrode 420 to set the bias voltage when a stack is placed on the electrode 420. A process wafer 466 is placed over the electrode 420. A temperature controller 434 provides temperature control fluid to a thermal uniformity layer 436 of the pinnacle 472. In some embodiments, the temperature controller 434 and thermal channels 324, shown in FIG. 3, provide a temperature control system. In some embodiments, the thermal fins 328 provide a temperature control system. A controller 424 controls the plasma power supply 406, the temperature controller 434, and the wafer bias voltage power supply 416.

The plasma power supply 406 and the wafer bias voltage power supply 416 may be configured to operate at specific radio frequencies such as, for example, 13.56 megahertz (MHz), 27 MHz, 2 MHz, 60 MHz, 400 kilohertz (kHz), 2.54 gigahertz (GHz), or combinations thereof. Plasma power supply 406 and wafer bias voltage power supply 416 may be appropriately sized to supply a range of powers in order to achieve desired process performance. For example, in one embodiment, the plasma power supply 406 may supply the power in a range of 50 to 5000 Watts, and the wafer bias voltage power supply 416 may supply a bias voltage in a range of 20 to 2000 volts (V). In addition, the TCP coil 410 and/or the electrode 420 may be comprised of two or more sub-coils or sub-electrodes. The sub-coils or sub-electrodes may be powered by a single power supply or powered by multiple power supplies.

As shown in FIG. 4, the semiconductor processing chamber system 400 further includes a gas source/gas supply mechanism 430. The gas source 430 is in fluid connection with semiconductor processing chamber 404 through a gas inlet, such as a gas injector 440. The gas injector 440 has at least one borehole 441 to allow gas to pass through the gas injector 440 into the semiconductor processing chamber 404. The gas injector 440 may be located in any advantageous location in the semiconductor processing chamber 404 and may take any form for injecting gas. Preferably, however, the gas inlet may be configured to produce a “tunable” gas injection profile. The tunable gas injection profile allows independent adjustment of the respective flow of the gases to multiple zones in the semiconductor process chamber 404. More preferably, the gas injector is mounted to the dielectric inductive power window 412. The gas injector may be mounted on, mounted in, or form part of the power window. The process gases and by-products are removed from the semiconductor process chamber 404 via a pressure control valve 442 and a pump 444. The pressure control valve 442 and pump 444 also serve to maintain a particular pressure within the semiconductor processing chamber 404. The pressure control valve 442 can maintain a pressure of less than 1 torr during processing. An edge ring 460 is placed around a top part of the electrode 420. The gas source/gas supply mechanism 430 is controlled by the controller 424. A Kiyo by Lam Research Corp. of Fremont, CA, may be used to practice an embodiment.

In some embodiments, a refractory metal component body is able to withstand the higher temperature ALD process without losing mechanical strength and/or detempering. Stainless steel, NSAs, and Ti have little to no change in material properties when exposed to ALD temperatures up to 400° C. SAE 316L grade stainless steel does not change phase until above 600° C. and does not melt until above 1300° C. Ti-6Al-4V, as another example, does not change phase until above 900° C. and does not melt until above 1600° C. NSAs, for example, can sustain 8,000 hours of aging at over 800° C. and have no loss in ultimate tensile strength. The refractory metal maintains sufficient strength to maintain a vacuum after being subjected to heating. In contrast, aluminum substrates will change material properties significantly, such as loss of strength, when exposed to temperatures above 200° C. for periods longer than 10 hours. A16061 T6 will lose over 30 percent of its tensile yield strength when exposed to 200° C. for 10 hours due to the growth of Mg₂Si secondary phases that reduce the effectiveness of grain boundary pinning. A resulting aluminum component body might not be able to hold a vacuum after heating. The aluminum layer 212 is mechanically supported by the refractory metal component body 204 so that maintaining a vacuum seal is not dependent on the mechanical strength of the aluminum layer 212 but instead is dependent on the strength of the refractory metal component body 204. In addition, in some embodiments, the refractory metal component body is highly resistant to corrosion when exposed to various plasma chemistries. SAE 316L grade stainless steel and AL-6XN stainless steel are corrosion resistant to halogen containing plasma. In addition, refractory metal component bodies provide fewer contaminants. The fluorides of Fe, Ni, and Co (which will form when stainless steel and NSAs are exposed to plasma chemistries) have melting points over 900° C. and will be difficult to volatilize like other plasma resistant materials and therefore causes fewer contaminants. Forming the component body out of refractory metals may provide manufacturing and/or design advantages, since the refractory metals may be denser and stronger. The refractory metals may allow for thinner walls. The refractory metals may allow for thinner and more complex cooling fins.

In some embodiments, the coating 216 deposited by ALD is at least one of a metal oxide, a metal fluoride, and a metal oxyfluoride, wherein the coating is at least 99% pure by weight and has a porosity of less than 0.1%. In some embodiments, the coating 216 comprises at least one of yttria (Y₂O₃), yttrium trifluoride (YF₃), hafnium oxide (HfO₂), yttrium aluminum oxide, lanthanide oxide, and lanthanide fluoride. In some embodiments, the coating 216 comprises a pyrochlore. A pyrochlore is a mineral with a general formula of A₂B₂O₇ or A₂B₂O₆, where A and B are 3+ and 4+ metal cations, respectively. Pyrochlore materials are crystalline but accommodate considerable variation in their crystalline structure and stoichiometry. In some embodiments, there may be up to 10% excess A or B site cations. In some embodiments, the pyrochlore comprises at least one of zirconium and hafnium and at least one of lanthanum (La), samarium (Sm), yttrium (Y), erbium (Er), cerium (Ce), gadolinium (Gd), ytterbium (Yb), and neodymium (Nd). In some embodiments, the pyrochlore comprises at least one of zirconium and hafnium and at least one of La, Ce, and Gd. In some embodiments, the pyrochlore consists essentially of zirconium and La. In some embodiments, the pyrochlore is formed from a material that does not form a volatile halide and is resistant to surface damage from ion bombardment.

In some embodiments, the coating 216 may be other mixed metal oxides than pyrochlores. For example, in some embodiments, the coating 216 may comprise yttrium aluminum oxide, such as yttrium aluminum garnet (YAG), yttrium aluminum monoclinic (YAM), and yttrium aluminum perovskite (YAP). In some embodiments, the coating 216 comprises at least one of yttrium, hafnium, zirconium, lanthanum, and a lanthanide. In some embodiments, the coating 216 comprises at least one of an oxide, fluoride, and oxyfluoride of at least one of yttrium, hafnium, zirconium, lanthanum, and a lanthanide. In some embodiments, the coating 216 deposited by ALD is at least one of a metal oxide, a metal fluoride, and a metal oxyfluoride, wherein the coating is at least 99.9% pure by weight and has a porosity of less than 0.1% and provides an improved plasma corrosion resistance and reduced contaminants.

In some embodiments, polishing the process facing surface 208 helps to minimize ALD defects. Component bodies of aluminum or aluminum alloys are soft and are very difficult to both polish and maintain a surface finish of less than 1 μm Ra. Stainless steel, NSA, and Ti component bodies can be polished to less than 1 μm Ra and the hardness of the materials can prevent handling damage that would cause particle generating defects. Stainless steel, NSAs, and Ti component bodies can be made for ALD type growth using many methods. Standard multicrystalline substrates can be used. In addition, single crystalline NSAs in the form of castings may be used. Additive manufacturing of stainless steel, NSAs, and Ti can also be used for more complex geometry substrates, especially for complex cooling channels.

Some embodiments may further comprise a high temperature process post-ALD coating. The high temperature process can be up to 1000° C. to achieve improved ALD coating properties such as stoichiometry (oxygen or fluorine relative to the metal precursor in the ALD film), crystallinity (increasing or decreasing amorphous content), and diffusion-based uniformity (such as homogenizing bimetallic precursor layers). Aluminum substrates would result in complete melting at the temperatures required. In some embodiments, for such post-processing activities, stainless steel and Ti component bodies can withstand post processing temperatures up to 600° C. to 800° C. NSA component bodies can withstand processing temperatures up to 1000° C.

In some embodiments, the at least 99% pure aluminum layer 212 provides an RF conduction path that is required in some embodiments. In some embodiments, the refractory metal component body does not have sufficient electrical conductivity to provide an RF power return or adequate uniformity. Inadequate uniformity may cause local heating with high resistances, or non-uniformities in the wafer environment of the processing chamber. Refractory metals generally have a higher electrical resistance than aluminum. As result, some embodiments provide the aluminum layer 212 on the process facing surface of the refractory metal component body to provide spatially controlled RF current flow. The aluminum layer 212 provides a low magnetic permeability layer at a sufficient thickness to provide, as an example, a uniform RF current return path. In some embodiments, the aluminum layer 212 has a thickness of 13 μm to 570 μm. In some embodiments, the aluminum layer has a thickness between 10 μm to 100 μm. In some embodiments, the aluminum layer 212 has a thickness between 30 μm to 500 μm. In some embodiments, the aluminum layer 212 has a thickness in the range of 1 to 3 electrical skin depths resulting from the skin effect. The aluminum skin depth for 60 megahertz (MHz) RF is 13 microns and for 400 kHz RF is 160 microns. Therefore, in some embodiments, if the aluminum layer 212 is three times the maximum skin depth the aluminum layer would be 480 microns. The aluminum layer 212 would have a thicker skin to allow more electrical flow compared to SAE 316L grade stainless steel since SAE 316L grade stainless steel at 60 MHz RF has a skin depth of 55 microns and at 400 kHz has a skin depth of 680 microns. Ti grade 2 at 60 MHz RF has a skin depth of 47 microns and at 400 kHz has a skin depth of 570 microns. In some embodiments, the aluminum layer 212 has no elemental contamination or inclusions allowing for a high quality anodization. In some embodiments, the aluminum layer 212 provides additional erosion or damage resistance to the environment in the semiconductor processing chamber. In one embodiment within a plasma processing chamber, aluminum exposed to a fluorine plasma forms nonvolatile aluminum fluoride providing additional protection.

In some embodiments, the thermal uniformity layer 320 is an aluminum layer bonded to a non-process facing surface of the component body 304. In some embodiments, the bonding is by at least one of metal bonding, clamping, or the use of a high thermally conductive adhesive. In some embodiments, the thermal uniformity layer 320 is an aluminum annulus. In some embodiments, the thermal uniformity layer 320 provides azimuthal temperature uniformity and allows local thermal breaks.

While this disclosure has been described in terms of several preferred embodiments, there are alterations, modifications, permutations, and various substitute equivalents, which fall within the scope of this disclosure. It should also be noted that there are many alternative ways of implementing the methods and apparatuses of the present disclosure. It is therefore intended that the following appended claims be interpreted as including all such alterations, modifications, permutations, and various substitute equivalents as fall within the true spirit and scope of the present disclosure. As used herein, the phrase “A, B, or C” should be construed to mean a logical (“A OR B OR C”), using a non-exclusive logical “OR,” and should not be construed to mean ‘only one of A or B or C. Each step within a process may be an optional step and is not required. Different embodiments may have one or more steps removed or may provide steps in a different order. In addition, various embodiments may provide different steps simultaneously instead of sequentially.

What is claimed is:

1. A component for use in a semiconductor processing chamber, comprising:
a component body with a process facing surface, wherein the component body comprises at least one of iron, iron alloy, nickel, nickel alloy, titanium, and titanium alloy; and
a coating over the process facing surface, wherein the coating comprises at least one of a metal oxide, a metal fluoride, and a metal oxyfluoride, wherein the coating is at least 99% by weight pure and has a porosity of less than 0.1%.

2. The component, as recited in claim 1, wherein the coating has a thickness in a range of 50 nm to 6000 nm.

3. The component, as recited in claim 1, wherein the coating is in direct contact with the process facing surface of the component body.

4. The component, as recited in claim 1, further comprising an aluminum layer between the process facing surface of the component body and the coating.

5. The component, as recited in claim 1, further comprising a thermal uniformity cladding over a surface of the component body that is not a process facing surface.

6. The component, as recited in claim 5, wherein the thermal uniformity cladding comprises aluminum.

7. The component, as recited in claim 5, further comprising a temperature control system for controlling a temperature of the thermal uniformity cladding.

8. The component, as recited in claim 1, wherein the component body comprises a stainless steel that is resistant to corrosion from halogen containing plasma.

9. The component, as recited in claim 1, wherein the component body comprises at least one of Ti-6A1-4V, NSA, SAE 316L grade stainless steel, and AL-6XN stainless steel.

10. The component, as recited in claim 1, wherein the coating comprises at least one of yttria, yttrium trifluoride, hafnium oxide, yttrium aluminum oxide, lanthanide oxide, and lanthanide fluoride.

11. The component, as recited in claim 1, wherein the component body comprises stainless steel.

12. The component, as recited in claim 1, wherein the component body comprises a titanium alloy.

13. A method for making a component for use in a semiconductor processing chamber, comprising:
providing a component body comprising at least one of iron, iron alloy, nickel, nickel alloy, titanium, and titanium alloy with a process facing surface; and
providing an atomic layer deposition coating over the process facing surface of the component body, wherein the atomic layer deposition coating comprises at least one of a metal oxide, a metal fluoride, and a metal oxyfluoride.

14. The method, as recited in claim 13, further comprising depositing an aluminum layer over the process facing surface of the component body before providing the atomic layer deposition coating over the process facing surface of the component body.

15. The method, as recited in claim 14, wherein the depositing the aluminum layer comprises depositing the aluminum layer by at least one of electroplating and cold spraying on the process facing surface before providing the atomic layer deposition.

16. The method, as recited in claim 13, further comprising providing a thermal uniformity cladding over a surface of the component body that is not a process facing surface.

17. The method, as recited in claim 16, wherein the thermal uniformity cladding comprises aluminum.

18. The method, as recited in claim 13, further comprising providing a temperature control system for controlling a temperature of the component body.

19. The method, as recited in claim 13, wherein the component body comprises a stainless steel that is resistant to corrosion from halogen containing plasma.

20. The method, as recited in claim 13, wherein the component body comprises at least one of Ti-6A1-4V, NSA, SAE 316L grade stainless steel, and AL-6XN stainless steel.

21. The method, as recited in claim 13, wherein the component body comprises stainless steel.

22. The method, as recited in claim 13, wherein the component body comprises a titanium alloy.
